(19) United States
(12) Patent Application Publication
(10) Pub. No.: US 2007/0001671 A1
(43) Pub. Date: Jan. 4, 2007

(54) Magnetostrictive MEMS based magnetometer

(76) Inventors: Rudolph V. Park, Columbia, MD (US); Dennis K. Wickenden, Woodbine, MD (US)

Correspondence Address: THE JOHNS HOPKINS UNIVERSITYAPPLIED PHYSICS LABORA;OFFICE OF PATENT COUNSEL, 11100 JOHNS HOPKINS ROAD, MAIL STOP 7-156, LAUREL, MD, 20723-6099, US

(21) Appl. No.: 11/478,481

(22) Filed: Jun. 29, 2006

Related U.S. Application Data
(60) Provisional application No. 60/695,272, filed on Jun. 30, 2005.

(51) Int. Cl. G01R 33/02

(52) U.S. Cl. 324/244

(57) ABSTRACT

A magnetostrictive microelectromechanical system (MEMS) element based magnetometer includes a MEMS element with any type of magnetostrictive material. The MEMS element can be made with or coated by the magnetostrictive material. The magnetometer can include a frequency measuring device, such as an oscilloscope, a frequency counter, a wave meter, a spectrum analyzer or the like. The magnetostrictive MEMS element can be used as a resonator in any type of oscillator circuit, such as a Pierce, a Colpitts, or a Clapp oscillator circuit. The magnetometer can be calibrated. The magnetostrictive MEMS element can be placed proximate a magnetic field, a resonant frequency of the magnetostrictive MEMS element proximate the magnetic field can be determined, and a property of the magnetic field can be determined based on a change in the resonant frequency of the magnetostrictive MEMS element proximate the magnetic field.

### CROSS-REFERENCE TO RELATED APPLICATIONS

This application claims the benefit of U.S. Provisional Application No. 60/695,272, filed Jun. 30, 2005, the contents of which are incorporated herein by reference.

### BACKGROUND OF THE INVENTION 1. Field of the Invention

The present invention generally relates to magnetometers and, more particularly, to a magnetostrictive micro-electromechanical system (MEMS) based magnetometer.

2. Description of the Related Art

Magnetometers can measure the magnitude and, sometimes, the direction of a magnetic field, and are used in a variety of applications. For example, magnetometers can be used for applications in transportation, environmental science, oceanography, biomedicine, space physics, etc. Numerous types of magnetometers are known including, for example, Hall probe magnetometers, flux gate magnetometers, and superconducting quantum interference detector (SQUID) type magnetometers.

Hall probe magnetometers have a sensitivity resolution of about 10⁻¹ Oersted (Oe)/Hertz (Hz)^{1/2}, and work by sensing a voltage change across a conductor placed in a magnetic field. Hall probe magnetometers are the least sensitive types of magnetometers and cannot be used where great sensitivity is needed. Flux gate magnetometers have a sensitivity resolution of about 10⁻⁶ Oe/Hz^{1/2}, and use a magnetic core surrounded by an electromagnetic coil. Flux gate magnetometers are constant current devices that draw sufficient current to saturate the flux gate core, thereby consuming a large amount of power and continually dissipating the power. SQUID type magnetometers have a sensitivity resolution of about 10⁻¹⁰ Oe/Hz^{1/2}, and use a superconducting element that is cooled to liquid gas temperatures. Due to the cooling requirements of SQUID type magnetometers, their sizes and operating costs are great.

Micro-electromechanical system (MEMS) elements are used in numerous applications. For example, MEMS elements can be used as small and accurate sensors and actuators for applications associated with, for example, temperature, humidity, vibration, acceleration, pressure, etc. MEMS oscillators are being developed as substitutes for crystal oscillators in wireless communication systems and signal processing applications.

A conventional oscillator circuit 100 is shown in FIG. 5. The oscillator circuit 100 may be referred to as a Pierce, Colpitts, or Clapp oscillator circuit depending whether node 110, 120, or 130, respectively, is an AC ground. Pierce oscillators resonate close to the resonant frequency of their mechanical structure. As illustrated, the oscillator 100 can include the resonator 140, a transistor M1, a first capacitor C1, and a second capacitor C2. Capacitance C0 is a shunt capacitance and corresponds to electrode and any stray capacitance associated with the oscillator 100.

A need exists for a magnetometer that is inexpensive, small in size, consumes low power, does not need a magnetic core, and does not need capacitance measurements.

### SUMMARY OF THE INVENTION

Accordingly, it is an object of the present invention to provide a magnetostrictive MEMS based magnetometer and a method for determining a magnetic field property.

According to one aspect of the present invention, a magnetometer includes an MEMS element with magnetostrictive material, wherein the magnetometer determines a property of an external magnetic field by determining a change in frequency of the magnetostrictive MEMS element. The magnetostrictive material can be any type of magnetostrictive material, such as an alloy of iron and an earth metal element, an alloy of nickel and an earth metal element, Terfenol-D, etc. The MEMS element can be made with or coated by the magnetostrictive material. The magnetometer can include a frequency measuring device, such as an oscilloscope, a frequency counter, a wave meter, a spectrum analyzer, etc. The MEMS element can be used as a resonator in an oscillator circuit, such as a Pierce, Colpitts, or Clapp oscillator circuit. The magnetometer can be calibrated based on frequency.

According to another aspect of the present invention, a method for determining a magnetic field property includes providing a MEMS element with magnetostrictive material, placing the magnetostrictive MEMS element proximate a magnetic field, determining a resonant frequency of the magnetostrictive MEMS element proximate the magnetic field, and determining a property of the magnetic field by determining a change in frequency of the magnetostrictive MEMS element. The method can provide the magnetostrictive material as any type of magnetostrictive material, such as an alloy of iron and an earth metal element, an alloy of nickel and an earth metal element, Terfenol-D, etc., and can make or coat the MEMS element with the magnetostrictive material. The method can provide a frequency measuring device, such as an oscilloscope, a frequency counter, a wave meter, a spectrum analyzer, etc. The method can provide the magnetostrictive MEMS element as a resonator for an oscillator circuit, such as a Pierce, Colpitts, or Clapp oscillator circuit. The method can calibrate the magnetometer based on frequency.

### BRIEF DESCRIPTION OF THE DRAWINGS

The above and other objects, features and advantages of the present invention will be more apparent from the following detailed description taken in conjunction with the accompanying drawings, in which:

FIG. 1 is a diagram of a magnetostrictive MEMS based magnetometer according to the present invention;

FIG. 2 is a magnetostrictive MEMS based magnetometer process according to the present invention;

FIG. 3 is a Pierce oscillator circuit with a magnetostrictive MEMS element as a resonator according to the present invention;

FIG. 4 is a clamped-clamped beam model of a MEMS element; and

FIG. 5 is a diagram of a conventional oscillator.

### DESCRIPTION OF THE PREFERRED EMBODIMENTS

Hereinafter, preferred embodiments according to the present invention will be described with reference to the accompanying drawings. The same reference numerals are used to designate the same elements as those shown in other drawings. In the following description, a detailed description of known functions and configurations incorporated herein will be omitted when it may obscure the subject matter of the present invention.

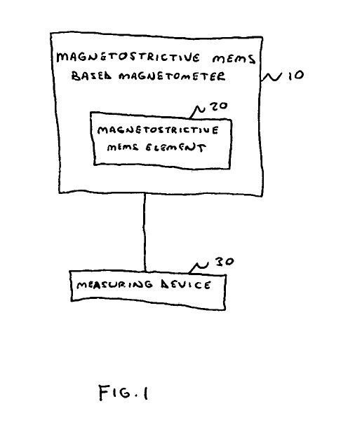

Referring to the drawings, FIG. 1 shows a magnetostrictive MEMS based magnetometer 10 according to the present invention. The magnetometer 10 includes a MEMS element 20 that can be made with or coated by a magnetostrictive material. As used herein, a “magnetostrictive MEMS” or “magnetostrictive MEMS element” refers to any type of MEMS element made with or coated by a magnetostrictive material. The magnetostrictive MEMS element 20 has a resonant frequency ω₀ and can be calibrated. The magnetostrictive MEMS element 20 can be placed proximate a magnetic field B, and a determination can be made as to a property, such as the magnitude, of the magnetic field B. The resonant frequency coo of the magnetostrictive MEMS element 20 proximate the magnetic field B varies as a function of the magnetic field B.

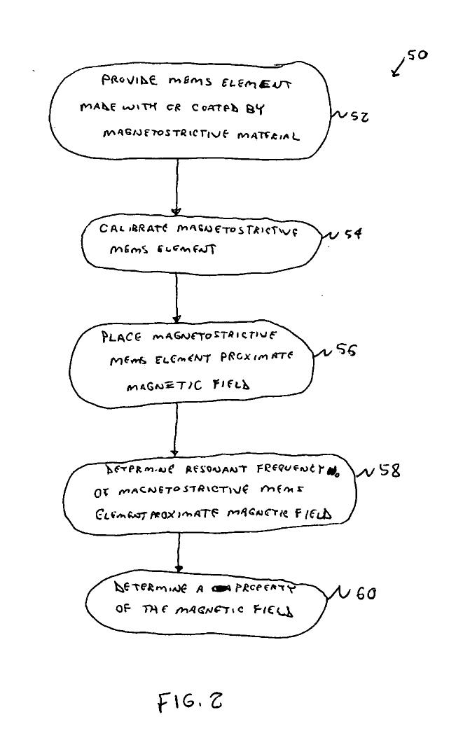

FIG. 2 shows steps involved in a magnetostrictive MEMS based magnetometer process. The process initially provides a MEMS element made with or coated by magnetostrictive material (step 52). The magnetostrictive MEMS element can be calibrated (step 54). The magnetostrictive MEMS element is then placed proximate a magnetic field B (step 56). The resonant frequency ω₀ of the magnetostrictive MEMS element proximate the magnetic field B is then determined (step 58). A property of the magnetic field B can then be determined (step 60).

The magnetostrictive MEMS based magnetometer 10 can be configured by using the oscillator circuit 100, shown in FIG. 5, fabricated through use of MEMS processing techniques. As described above, the oscillator circuit 100 is a conventional oscillator circuit, referred to as a Pierce, Colpitts, or Clapp oscillator circuit, depending whether node 110, 120, or 130, respectively, is an AC ground. Pierce oscillators resonate close to the resonant frequency of their mechanical structure.

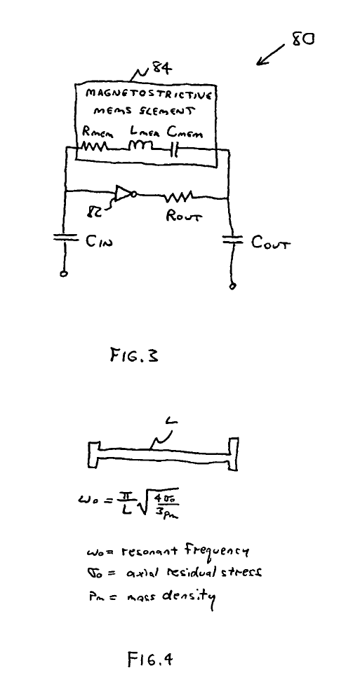

FIG. 3 shows a Pierce oscillator 80 that includes a magnetostrictive MEMS element 84 as a resonator according to the present invention. The Pierce oscillator 80 includes an amplifier 82, a capacitor Cᵢₙ, a capacitor Cₒᵤₜ, a resistor Rₒᵤₜ, and the magnetostrictive MEMS element 84. The magnetostrictive MEMS element 84 is modeled with a resistor Rₘₑₘ, an inductor Lₘₑₘ, and a capacitor Cₘₑₘ.

Any or all portions of the oscillator 80 and, in particular, the resonator 84, can be made with or coated by any type of magnetostrictive material that can cause deformation when subjected to a magnetic field. For example, the magnetostrictive material can include Terfenol-D, material with an alloy of iron and an earth metal element, such as an Al—Fe, Ni—Fe, R—Fe, etc., based magnetostrictive material, material with an alloy of nickel and an earth metal element, etc. The resonator 84 can be configured in a variety of ways. For example, the resonator 84 can have a comb-like geometry to enhance its performance, and can have a spring-like shuttle that is anchored at its center to the ground plane. The resonator 84 can support two combs of fingers and allow them to oscillate. The oscillator 80 can be made according to standard MEMS fabrication techniques. Different baseline resonant frequencies coo of the oscillator 80, e.g. resonant frequencies ω₀ occurring in the presence of minimal external magnetic fields, can be obtained by configuring the magnetostrictive MEMS element 84 with different widths and lengths. Various configurations of the magnetostrictive MEMS based magnetometer 10 can be obtained through various MEMS implementations.

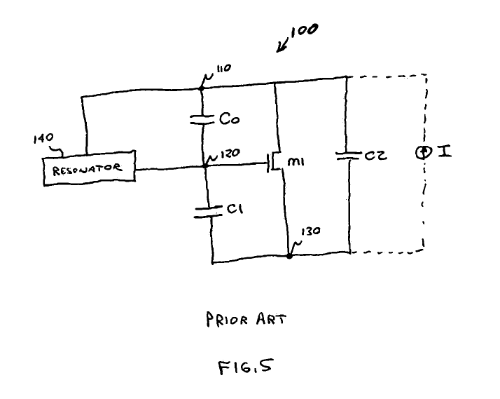

When a magnetostrictive MEMS based magnetometer 10 according to the present invention is produced using an oscillator circuit 100, as shown in FIG. 5, in a MEMS configuration as described above, the oscillator 100 can, for example, generally be modeled according to a clamped-clamped beam MEMS model, as shown in FIG. 4, where the resonant frequency ω₀ may be characterized as
ω₀=π/L\sqrt{4σ₀/3ρₘ}

where ω₀=resonant frequency
L=length of the beam
σ₀=axial residual stress
ρₘ=mass density
   The actual resonant frequency coo of such an oscillator 100 depends on the stiffness and mass of the oscillator 100, and can be determined according to the geometry of the oscillator 100 and the properties of materials of the oscillator 100.

The magnetostrictive MEMS magnetometer 10, shown in FIG. 1, can be calibrated by determining the resonant frequency coo of the magnetostrictive MEMS element 20 over a range of magnetic fields through use of a frequency measuring device 30. The frequency measuring device 30 can detect the frequency of the magnetostrictive MEMS element 20. As described above, the resonant frequency ω₀ of the magnetostrictive MEMS element 20 is based on the stiffness and mass of the MEMS element 20. Since the mass of the magnetostrictive MEMS element 20 does not change, measured parameters other than the frequency obtained through use of a frequency measuring device 30, such as an oscilloscope, a frequency counter, a wave meter, a spectrum analyzer or the like, enable the determination of the variation of the resonant frequency of the magnetostrictive MEMS element 20 with the external magnetic field B.

The resonant frequency ω₀ of the magnetostrictive MEMS element 20 generally varies linearly over a magnetic field strength range between two non-linear frequency regions, such that the resonant frequency of the magnetostrictive MEMS element 20 varies a function of the external magnetic field B, e.g. ω₀=ƒ(B). When the resonant frequency ω₀ of the magnetostrictive MEMS element is determined in the presence of minimal external magnetic field, and the resonant frequency ω₀ of the magnetostrictive MEMS element is then determined proximate an external magnetic field B, a property of the magnetic field B, such as the magnetic field strength, can then be determined based on the fact that the resonant frequency ω₀ is a function, such as a linear function, of the external magnetic field B, or ω₀=ƒ(B). A property of the magnetic field B can then be determined.

The present invention as described above provides a magnetometer where a property of an external magnetic field B can easily be determined through simple measurement of the resonant frequency of an included magnetostrictive MEMS element. The magnetostrictive MEMS based magnetometer is inexpensive, small in size, consumes low power, does not need a magnetic core, and does not need capacitance measurements.

Although a preferred embodiment of the present invention has been described for illustrative purposes, those skilled in the art will appreciate that various modifications, additions and substitutions are possible, without departing from the scope and spirit of the invention as disclosed in the accompanying claims, including the full scope of equivalents thereof.

What is claimed is:

1. A magnetometer comprising a microelectromechanical system (MEMS) element with magnetostrictive material (magnetostrictive MEMS element),
wherein the magnetometer determines a property of external magnetic field by determining a change in frequency of the magnetostrictive MEMS element.

2. The magnetometer according to claim 1, wherein the magnetostrictive material is an alloy of iron and an earth metal element.

3. The magnetometer according to claim 1, wherein the magnetostrictive material is an alloy of nickel and an earth metal element.

4. The magnetometer according to claim 1, wherein the magnetostrictive material is Terfenol-D.

5. The magnetometer according to claim 1, wherein the MEMS element is made with the magnetostrictive material.

6. The magnetometer according to claim 1, wherein the MEMS element is coated by the magnetostrictive material.

7. The magnetometer according to claim 1, further comprising a frequency measuring device.

8. The magnetometer according to claim 7, wherein the frequency measuring device is one of an oscilloscope, a frequency counter, a wave meter, and a spectrum analyzer.

9. The magnetometer according to claim 1, wherein the magnetostrictive MEMS element is a resonator of one of a Pierce oscillator circuit, a Colpitts oscillator circuit, and Clapp oscillator circuit.

10. The magnetometer according to claim 1, wherein the magnetometer is calibrated based on frequency.

11. A method for determining a magnetic field property, the method comprising:
providing a microelectromechanical system (MEMS) element with magnetostrictive material (magnetostrictive MEMS element);
placing the magnetostrictive MEMS element proximate a magnetic field;
determining a resonant frequency of the magnetostrictive MEMS element proximate the magnetic field; and
determining a property of the magnetic field by determining a change in frequency of the magnetostrictive MEMS element proximate the magnetic field.

12. The method according to claim 11, wherein the providing a MEMS element step further comprises providing the magnetostrictive material as an alloy of iron and an earth element.

13. The method according to claim 11, wherein the providing a MEMS element step further comprises providing the magnetostrictive material as an alloy of nickel and an earth element.

14. The method according to claim 11, wherein the providing a MEMS element step further comprises providing the magnetostrictive material as Terfenol-D.

15. The method according to claim 11, wherein the providing a MEMS element step further comprises making the MEMS element with the magnetostrictive material.

16. The method according to claim 11, wherein the providing a MEMS element step further comprises coating the MEMS element with the magnetostrictive material.

17. The method according to claim 11, further comprising providing a frequency measuring device.

18. The method according to claim 17, wherein the providing a frequency measuring device step further comprises providing one of an oscilloscope, a frequency counter, a wave meter, and a spectrum analyzer.

19. The method according to claim 11, further comprising calibrating the magnetometer based on frequency.

20. The method according to claim 11, wherein the providing a MEMS element step further comprises providing the MEMS element as a resonator in one of a Pierce oscillator circuit, a Colpitts oscillator circuit, and Clapp oscillator circuit.
